(19) United States
(12) Patent Application Publication
(10) Pub. No.: US 2011/0291153 A1
(43) Pub. Date: Dec. 1, 2011

(54) CHIP SUBMOUNT, CHIP PACKAGE, AND FABRICATION METHOD THEREOF

(76) Inventors: Ming-Kun Yang, Taoyuan County (TW); Tsang-Yu Liu, Hsinchu County (TW); Long-Sheng Yeou, Hsinchu County (TW)

(21) Appl. No.: 13/118,602

(22) Filed: May 31, 2011

Related U.S. Application Data
(60) Provisional application No. 61/349,902, filed on May 31, 2010.

(51) Int. Cl. H01L 33/48

(52) U.S. Cl. 257/99; 257/E33.056

(57) ABSTRACT

A light-emitting diode submount includes a base, a through silicon via and a sealing layer. The base has a die side and a back side. The through silicon via penetrates the base to connect the die side and the back side. The through silicon via includes a conoidal-shaped portion converging from the back side toward the die side, and a vertical via portion connects with the conoidal-shaped portion. A sealing layer seals the vertical via portion.

### CROSS REFERENCE TO RELATED APPLICATIONS

This application claims the benefit of U.S. provisional application No. 61/349,902 filed May 31, 2010.

### BACKGROUND OF THE INVENTION

1. Field of the Invention

This invention relates generally to a chip submount, a chip package, and a fabrication method thereof, and more specifically, to a chip submount, a chip package having conoidal-shaped through-silicon-via (TSV) structures, and a fabrication method thereof.

2. Description of the Prior Art

The light emitting diode (LED) is widely used as the source of a guiding light or a display panel. The LED not only can directly transfer electrical energy to light energy with high efficiency, but also has advantages of a long lifetime and saving electricity. Therefore the LED plays an important role in illumination or display art.

Typically, an LED die is disposed on a submount. The LED die is connected with a packaged substrate or another electronic device through the submount, where the submount directly affects the electrical quality and thermal performance of the packaged light emitting diode. Refer to FIG. 1, which schematically depicts a sectional view of a light-emitting diode submount in the prior art. As shown in FIG. 1, the LED submount 100 includes a base 110, a through silicon via 120, an insulating layer 130, a seed layer 140, a first metal layer 150 and a second metal layer 160. The through silicon via 120 is a nearly vertical pillar-shaped through via. The seed layer 140 may be a copper seed layer, the first metal layer 150 may be an electroplating copper layer, and the second metal layer 160 may be an electroplating nickel layer, an electroplating gold layer, or an electroplating nickel or gold layer.

However, there are still several disadvantages in the above prior art technique that need to be improved. For instance, the inner surface of the through silicon via 120 has a rough and uneven surface (as shown in FIG. 1) after etching. This leads to a non-uniform thickness of the insulating layer 130 formed on the inner surface of the through silicon via 120, hence resulting in poor insulation and leakage. Furthermore, due to the vertical pillar-shaped structure and small via diameter of the through silicon via 120, the sputtering quality of the seed layer 140 is not easy to control.

In addition, the silver gel needed for fixing the LED die on the submount easily flows into the through silicon via 120 due to miniaturization. The silver gel may contaminate the bonding pads. One approach to avoiding this pad contamination problem is filling the through silicon via 120 with electroplating metal by an electroplating method to prevent the silver gel from flowing into the through silicon via 120. However, the prior art approach is time-consuming and leads to high manufacturing costs.

### SUMMARY OF THE INVENTION

This invention provides a chip submount, a chip package having conoidal-shaped through silicon via (TSV) structures and fabrication methods thereof, which seals one end of the TSV by a sealing layer to solve the aforementioned problems.

According to a preferred embodiment of the present invention, a chip submount includes a base, a through silicon via and a sealing layer. The base has a die side and a back side. The through silicon via penetrates the base to connect the die side and the back side, wherein the through silicon via includes a conoidal-shaped portion converging from the back side toward the die side and a vertical via portion connects with the conoidal-shaped portion. A sealing layer seals the vertical via portion.

In one embodiment of this invention, a via diameter of the vertical via portion is substantially equal to a lower diameter of the conoidal-shaped portion and the via diameter of the vertical via portion ranges between about 10 μm-50 μm. The conoidal-shaped portion further includes an upper diameter, which ranges between about 250 μm-320 μm. In one embodiment, the base is a silicon base. The sealing layer is composed of a conductive material. A chip die is mounted on the die side. The conoidal-shaped portion has a smooth surface.

In one embodiment of this invention, the chip submount further includes an insulating layer at least covering the surface of the conoidal-shaped portion and the vertical via portion, wherein the insulating layer includes a chemical vapor deposition (CVD) silicon oxide layer, an epoxy resin layer, a photoresist layer or a silicon oxide layer.

In one embodiment of this invention, the chip submount further includes a seed layer covering the insulating layer, wherein the seed layer includes titanium, tungsten, copper or alloys thereof. Otherwise, the chip submount further includes an electroplating metal layer located on the seed layer, wherein the electroplating metal layer includes copper, nickel, gold or alloys thereof. The seal layer includes the electroplating metal layer. A protrusion of the electroplating metal layer seals the vertical via portion and constitutes the sealing layer.

According to a preferred embodiment of the present invention, a chip package includes a chip submount explained above; a chip die disposed on the chip submount; and at least a wire connecting an electrode of the chip die to a bonding pad of the chip submount.

According to a preferred embodiment of the present invention, a method of fabricating a chip submount includes: providing a base having a die side and a back side; performing a first etching process to form a first vertical via in the back side; performing a second etching process to trim the first vertical via to a funnel-shaped via; polishing the back side of the base to make the funnel-shaped via become a through silicon via, wherein the through silicon via includes a conoidal-shaped portion converging from the back side toward the die side and a vertical via portion connecting with the conoidal-shaped portion; forming an insulating layer covering the surface of the through silicon via; forming a seed layer covering the insulating layer; forming a photoresist pattern on the insulating layer to define a redistribution layer circuit pattern; forming a metal layer on the seed layer uncovered by the photoresist pattern, wherein a protrusion of the metal layer seals the vertical via portion and constitutes a sealing layer; removing the photoresist pattern and removing the seed layer uncovered by the metal layer.

In one embodiment of this invention, the first vertical via has a first via diameter ranging between about 10 μm-40 μm and the via diameter of the vertical via portion is larger than the first via diameter, wherein the via diameter of the vertical via portion ranges between about 10 μm-50 μm and the via diameter of the vertical via portion is substantially equal to a lower diameter of the conoidal-shaped portion. The conoidal-shaped portion further includes an upper diameter ranging between about 250 μm-320 μm and the conoidal-shaped portion has a smooth surface.

In one embodiment of this invention, the base is a silicon base.

The die side is used for mounting a chip die. The insulating layer includes a chemical vapor deposition (CVD) silicon oxide layer, an epoxy resin layer, a photoresist layer, or a silicon oxide layer. The seed layer and the metal layer include titanium, tungsten, copper or alloys thereof. The metal layer is formed by electroplating.

In one embodiment of this invention, the first etching process is a dry etching process and the second etching process is a dry etching process. The through silicon via penetrates the base and connects the die side and the back side.

According to a preferred embodiment of the present invention, a method of fabricating a chip package includes: providing a chip submount fabricated by the above method; mounting a chip die on the chip submount; and connecting an electrode of the chip die to a bonding pad of the chip submount by using at least a wire.

According to a preferred embodiment of the present invention, a chip submount includes: a base, a through silicon via and a sealing layer. The base has a die side and a back side. The through silicon via connects the die side to the back side, wherein the through silicon via includes a conoidal-shaped portion converging from the back side toward the die side and the sealing layer seals one end of the through silicon via.

According to a preferred embodiment of the present invention, a chip package includes: a chip submount according to the above; a chip die mounted on the chip submount; and at least a wire connecting an electrode of the chip die to a bonding pad of the LED submount.

According to the above, the present invention provides a chip submount, a chip package having the sealing layer and the through silicon via having conoidal-shaped structures and fabrication methods thereof, to not only reduce the dosage of the electroplating metal in the through silicon via and reduce the electroplating cost, but also avoid the circuit leakages caused by the poor insulation in the through silicon via. Furthermore, this invention can also solve the problem of unevenly sputtering and electroplating metal in the through silicon via.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a sectional view of an LED submount in the prior art.

FIG. 2 schematically depicts a sectional view of an LED submount and an LED package in accordance with one preferred embodiment of this invention.

FIG. 3 schematically depicts a sectional view of an LED submount and an LED package in accordance with another preferred embodiment of this invention.

FIG. 4 schematically depicts a sectional view of an LED submount and an LED package in accordance with still another preferred embodiment of this invention.

FIG. 5A-5G schematically depicts a sectional flow chart of fabricating an LED submount.

### DETAILED DESCRIPTION

A light-emitting diode (LED) submount is described in the following as an example to represent the present invention, but it is not limited thereto. The present invention can be also applied to various submounts applicable for chips.

FIG. 2 schematically depicts a sectional view of a light-emitting diode (LED) submount and a LED package in accordance with one preferred embodiment of this invention. As shown in FIG. 2, an LED submount 200, an LED die 10 and a wire 20 are part of an LED package 300. The LED die 10 is disposed on the LED submount 200 and an electrode 30a on the bottom of the LED die 10 is electrically connected to a die pad 204 on the LED submount 200. The wire 20 connects the other electrode 30b of the LED die 10 to a bonding pad 202 of the LED submount 200. In this way, the LED die 10 can be electrically connected to a packaged support board or other electronic element (not shown in FIG. 2) through the LED submount 200.

In another embodiment, as shown in FIG. 3, an LED submount 200, an LED die 10 and two wires 20a and 20b are part of an LED package 300a. The LED die 10 is disposed on the LED submount 200 and the lower surface of the LED die 10 is isolated from and connected to the LED submount 200. The two wires 20a and 20b are respectively connected the two electrodes 30a and 30b of the LED die 10 to a die pad 204 and a bonding pad 202 of the LED submount 200. Thus, the LED die 10 can be connected to a packaged support board or other electronic element (not shown in FIG. 3) through the LED submount 200.

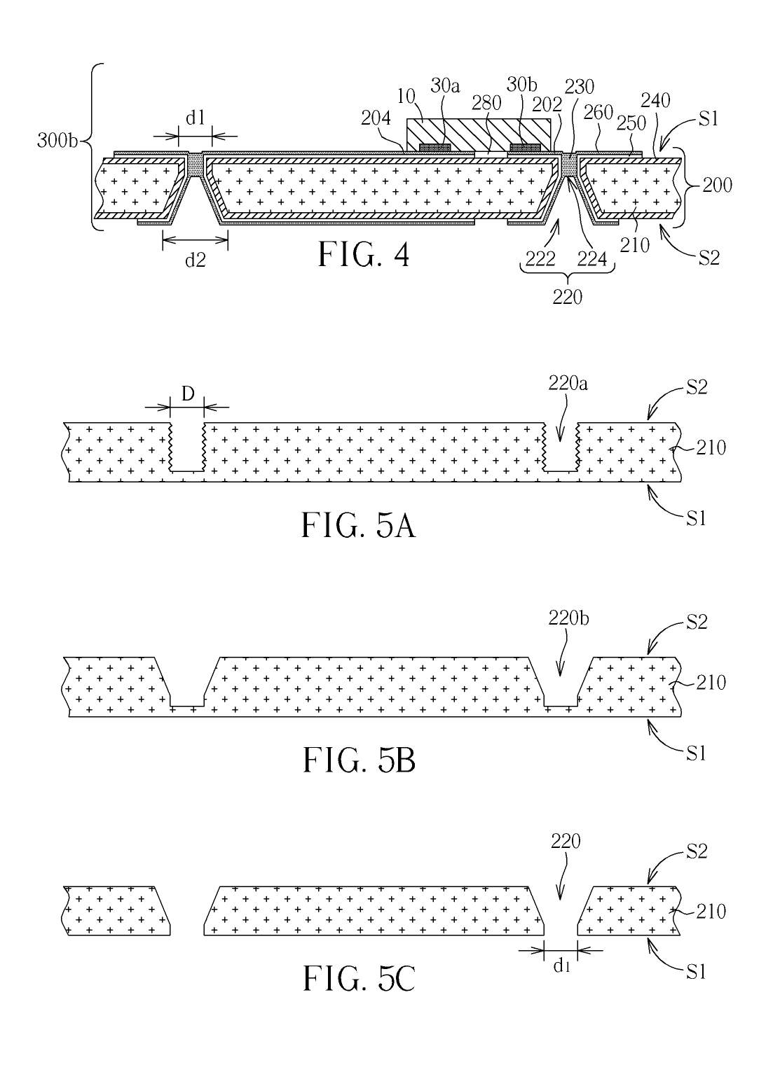

Instill another embodiment, as shown in FIG. 4, an LED submount 200 and an LED die 10 are part of an LED package 300b. The LED die 10 is disposed on the LED submount 200 and the two electrodes 30a and 30b located on the lower surface of the LED die 10 are directly respectively connected with the pad 204 and the bonding pad 202 of the LED submount 200 without being connected by wires. Basically, the LED die 10 covers the separate part 280 between the die pad 204 and the bonding pad 202, wherein the separate part 280 is selectively filled (1) or not filled (2) with insulating materials.

Moreover, as shown in FIG. 2, an LED submount 200 includes a base 210, a through silicon via 220 and a sealing layer 230. The base 210 has a die side S1 and a back side S2. The die side S1 is used for supporting the LED die 10 and the die side S1 has a conductive pattern distributed on it. The back side S2 is used for electrically connecting the support board and cooling plates are distributed on the back side S2 to shed heat while the LED die 10 works. In one embodiment, the base may be a silicon base having a well-cooling performance, but is not limited to this Moreover, the through silicon via 220 penetrates the base 210 to connect the die side S1 and the back side S2, wherein the through silicon via 220 includes the conoidal-shaped portion 222 converging from the back side S2 toward the die side S1 and a vertical via portion 224 connects with the conoidal-shaped portion 222. Otherwise, the sealing layer 230 seals the vertical via portion 224. The sealing layer 230 is a composition of a conductive material and the purpose of the sealing layer 230 is to prevent the silver gel from flowing into the through silicon via 220, wherein the conductive material may be copper, gold, other metal, or alloys thereof.

Furthermore, the LED submount 200 includes an insulating layer 240. In one case, the insulating layer 240 covers the surface of the base 210 and at least covers the surface of the conoidal-shaped portion 222 and the vertical via portion 224, but is not limited to this. In one embodiment, the insulating layer 240 may include a chemical vapor deposition (CVD) silicon oxide layer, an epoxy resin layer, a photoresist layer, or a silicon oxide layer, but it may also be formed by other insulating materials. Because the through silicon via 220 has an conoidal-shaped portion 222 having tapered structure, the high quality insulating layer 240 can be formed by chemical vapor deposition (CVD) method or spray coating method to reduce product costs. This achievement can not be approached in the prior art vertical pillar through silicon via 120, hence the vertical pillar through silicon via 120 is formed by the thermal oxidation method.

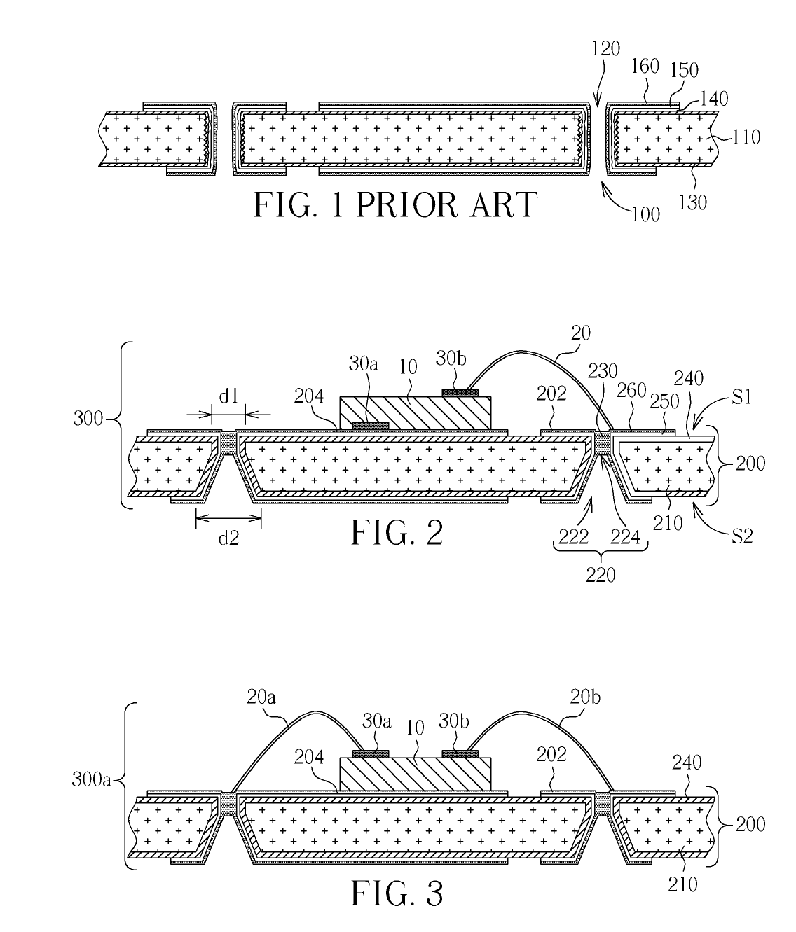

Otherwise, the LED submount 200 further includes a seed layer 250 covering the insulating layer 240, wherein the seed layer 250 includes titanium, tungsten, copper, or alloys thereof. The LED submount 200 further includes an electroplating metal layer 260 disposed on the seed layer 250, wherein the electroplating metal layer 260 includes copper, nickel, gold or alloys thereof. In one case, the sealing layer 230 includes the electroplating metal layer 260 and a portion of the electroplating metal layer 260 seals the vertical via portion 224 to constitute the sealing layer 230. It needs to be noted, however, that this invention just needs to seal the vertical via portion 224 of the through silicon via 220 to prevent the silver gel from flowing into the through silicon via 220 without filling the whole through silicon via 220. Compared to the prior art, in which the whole through silicon via 120 (as shown in FIG. 1) needs to be electroplated by gold or copper to avoid the silver gel overflowing and polluting, this invention can reduce the dosage of the electroplating metal and the electroplating time.

In the embodiment, the via diameter d1 of the vertical via portion 224 is substantially equal to a lower via diameter of the conoidal-shaped portion 222 and the conoidal-shaped portion 222 further includes an upper via diameter d2 located on the back side S2 of the base 210, wherein the upper via diameter d2 is larger than the lower via diameter d1. Compared to the prior art, the upper via diameter d2 may correspond to the vertical pillar via diameter of the through silicon via in the prior art and the upper via diameter d2 of the conoidal-shaped portion 222 is broadened from the lower via diameter d1. According to a preferred embodiment, the lower via diameter of the conoidal-shaped portion 222 or the via diameter d1 of the vertical via portion 224 may range between 10 μm and 50 μm and the upper via diameter d2 of the conoidal-shaped portion 222 may range between 250 μm and 320 μm, but is not limited to this. In general, an included angle between the inclined surface of the conoidal-shaped portion 222 and the horizontal plane may range between 70° and 90°, but in a preferred embodiment, the included angle between the inclined surface of the conoidal-shaped portion 222 and the horizontal plane may range between 72° and 75°. Thus, the conoidal-shaped portion 222 of this invention can prevent the problems of uneven inner surface of the via and circuit leakages in the prior art. The conoidal-shaped portion 222 of the invention has a smooth surface to solve the circuit leakage problem. Moreover, the insulating layer 240 covering the base 210 can have a uniform thickness and the seed layer or the electroplating metal layer is easier to be sputtered on the conoidal-shaped portion 222.

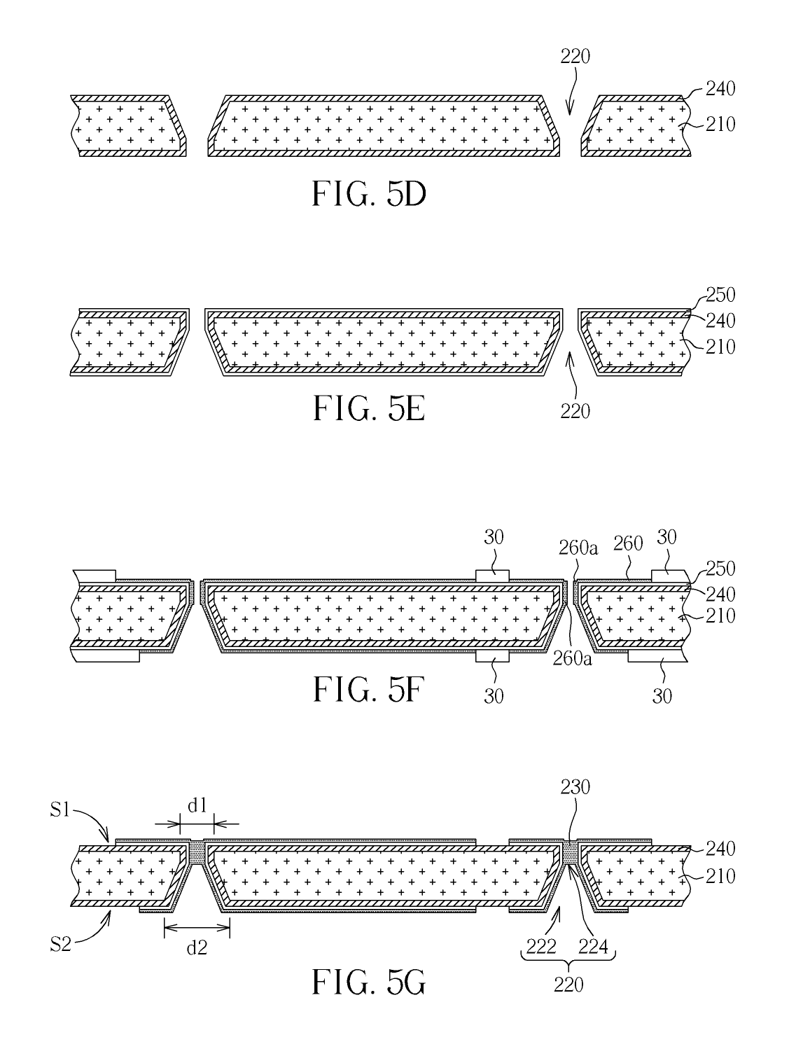

FIG. 5A-5G schematically depicts a sectional flow chart of fabricating an LED submount. Refer to FIG. 5A-5G, which illustrates the method for fabricating the LED submount 220 including providing a base 210 having the die side S1 and the back side S2 (as shown in FIG. 5A). The method also includes performing a first etching process to form the first vertical via 220a into the back side S2, wherein the first etching process is a dry etching process in this case and the first etching process may be a wet etching process in other case as well, but is not limited to this. The first vertical via 220a has a first via diameter D that ranges between 10 μm and 40 μm. The method then includes performing a second etching process to broaden the first vertical via 220a and trim it to a funnel-shaped via 220b, wherein the second etching process is a dry etching process in this embodiment, but it may be a wet etching process in another embodiment, or it may include a wet etching process performed after a dry etching process to form a more precisely predetermined hole shape (as sown in FIG. 5B). Subsequently, the method includes polishing the back side S2 of the base 210 by methods, such as chemical mechanical polishing (CMP) method, to make the funnel-shaped via 220b become the through silicon via 220 including the conoidal-shaped portion 222 converging from the back side S2 to the die side 51 and connecting with the vertical via portion 224 of the conoidal-shaped portion 222. In the embodiment, the first via diameter D is broadened in the second etching process, so the via diameter d1 of the vertical via portion 224 would be slightly larger than the first via diameter D (as shown in FIG. 5C). The method next includes forming an insulating layer 240 covering the surface of the through silicon via 220 and the insulating layer 240 may be formed by chemical vapor deposition (CVD) process, organic coating process, spray coating process or coating the insulating layer 240 by insulating materials made by photoresist (as shown in FIG. 5D). The method also includes forming the seed layer 250 covering the insulating layer 240 and the seed layer 250 may be formed by electroplating methods (as shown in FIG. 5E). The method also includes forming a photoresist pattern 30 on the insulating layer 240 to define a redistribution layer circuit pattern. The method additionally includes forming a metal layer 260 on the seed layer 250 uncovered by the photoresist pattern and sealing the vertical via portion 224 by a protrusion 260a of the metal layer 260 to constitute a sealing layer 230 (as shown in FIG. 5F), wherein the metal layer 260 can also be formed by the electroplating methods. Finally, the method includes removing the photoresist pattern and removing the seed layer 250 uncovered by the metal layer 260 to form the redistribution layer circuit pattern (as shown in FIG. 5G). In this way, the LED submount 200 process can be finished. Certainly, the LED die 10 can be disposed on the LED submount 200. An electrode 30a on the bottom of the LED die 10 can be electrically connected to a bonding pad 204 of the LED submount 200 and a wire 20 connects an electrode 30b of the LED die 10 to a die pad 202 of the LED submount 200 to form an LED subpackage 300 (as shown in FIG. 2). Perhaps, the LED die 10 can be disposed on the LED submount 200 and two wires 20a and 20b respectively electrically connect two electrodes 30a and 30b of the LED die 10 to a bonding pad 204 and a die pad 202 of the LED submount 200 to form an LED subpackage 300 (as shown in FIG. 3).

To sum up, this invention provides an LED submount, an LED package having the sealing layer and the through silicon via having conoidal-shaped structures, and fabrication methods thereof, to not only reduce the dosage of the electroplating metal in the through silicon via and the electroplating cost, but also reduce the roughness of the inner surface of the through silicon via and improve the thickness uniformity of the insulating layer formed on the inner surface of the through silicon via, therefore, avoiding circuit leakages caused by the poor insulation in the through silicon via. Furthermore, the through silicon via having conoidal-shaped structure can also work out the problem of sputtering difficulty of the seed layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chip submount, comprising:
a base having a die side and a back side;
a through silicon via penetrating the base to connect the die side and the back side, wherein the through silicon via comprises a conoidal-shaped portion converging from the back side toward the die side and a vertical via portion connecting with the conoidal-shaped portion; and
a sealing layer sealing the vertical via portion.

2. The chip submount according to claim 1, wherein a via diameter of the vertical via portion is substantially equal to a lower diameter of the conoidal-shaped portion.

3. The chip submount according to claim 1, wherein the base is a silicon base.

4. The chip submount according to claim 1, wherein the sealing layer is composed of a conductive material.

5. The chip submount according to claim 1, wherein a chip die is mounted on the die side.

6. The chip submount according to claim 1 further comprising an insulating layer at least covering surface of the conoidal-shaped portion and the vertical via portion.

7. The chip submount according to claim 6 further comprising a seed layer covering the insulating layer.

8. The chip submount according to claim 7, wherein the seed layer comprises titanium, tungsten, copper or alloys thereof.

9. The chip submount according to claim 7 further comprising an electroplating metal layer located on the seed layer.

10. The chip submount according to claim 9, wherein the electroplating metal layer comprises copper, nickel, gold or alloys thereof.

11. The chip submount according to claim 9, wherein the seal layer comprises the electroplating metal layer.

12. The chip submount according to claim 9, wherein a protrusion of the electroplating metal layer seals the vertical via portion and constitutes the sealing layer.

13. The chip submount according to claim 1, wherein the conoidal-shaped portion has a smooth surface.

14. A chip package, comprising:
a chip submount according to claim 1;
a chip die disposed on the chip submount; and
at least a wire connecting an electrode of the chip die to a bonding pad of the chip submount.

15. A chip submount, comprising:
a base having a die side and a back side;
a through silicon via connecting the die side to the back side, wherein the through silicon via comprises a conoidal-shaped portion converging from the back side toward the die side; and
a sealing layer sealing one end of the through silicon via.

16. A chip package, comprising:
a chip submount according to claim 15;
a chip die mounted on the chip submount; and
at least a wire connecting an electrode of the chip die to a bonding pad of the chip submount.

17. A chip package, comprising:
a chip submount according to claim 15; and
a chip die mounted on the chip submount, wherein two electrodes located on a lower surface of the chip die respectively electrically connect a bonding pad and a die pad disposed on the chip submount.

18. The chip package according to claim 17, wherein the chip die covers a separate part between the bonding pad and the die pad.

19. The chip package according to claim 18, wherein the separate part is filled with insulating material.

20. The chip package according to claim 18, wherein the separate part is not filled with insulating material.
